(19) United States
(12) Patent Application Publication
(10) Pub. No.: US 2026/0032979 A1
(43) Pub. Date: Jan. 29, 2026

(54) ELECTRONIC DEVICES COMPRISING EPITAXIAL POLYSILICON SOURCE CONTACTS AND RELATED SYSTEMS AND METHODS

(71) Applicant: Micron Technology, Inc., Boise, ID (US)

(72) Inventors: Andrew L. Li, Boise, ID (US); Kunal Shrotri, Boise, ID (US); Adam W. Saxler, Boise, ID (US); Sriram Balasubramanian, Boise, ID (US); Sidhartha Gupta, Boise, ID (US); Protyush Sahu, Boise, ID (US); Shashank Gupta, Singapore (SG); Milos Petrovic, Singapore (SG)

(21) Appl. No.: 19/250,480

(22) Filed: Jun. 26, 2025

Related U.S. Application Data
(60) Provisional application No. 63/675,929, filed on Jul. 26, 2024.

(51) Int. Cl. H10D 64/23; H10B 43/27; H10D 64/62

(52) U.S. Cl. CPC H10D 64/2527; H10B 43/27; H10D 64/62

(57) ABSTRACT

An electronic device that comprises a source stack comprising one or more conductive materials, a source contact adjacent to the source stack, tiers of alternating conductive materials and dielectric materials adjacent to the source contact, and pillars extending through the tiers and the source contact and into the source stack. At least a portion of the source contact comprises an epitaxial polysilicon material. Electronic systems and methods of forming the electronic device are also disclosed.

### CROSS-REFERENCE TO RELATED APPLICATION

This application claims the benefit under 35 U.S.C. § 119 (e) of U.S. Provisional Patent Application Ser. No. 63/675,929, filed Jul. 26, 2024, the disclosure of which is hereby incorporated herein in its entirety by this reference.

### TECHNICAL FIELD

Embodiments of the disclosure relate to the field of electronic device design and fabrication. More particularly, the disclosure relates to electronic devices having a source contact that includes at least a portion of epitaxial polysilicon, and to related electronic systems and methods for forming the electronic devices.

### BACKGROUND

Memory devices provide data storage for electronic systems. A Flash memory device is one of various memory device types and has numerous uses in modern computers and other electrical devices. A conventional Flash memory device may include a memory array that has a large number of charge storage devices (e.g., memory cells, such as non-volatile memory cells) arranged in rows and columns. In a NAND architecture type of Flash memory, memory cells arranged in a column are coupled in series, and a first memory cell of the column is coupled to a data line (e.g., a bit line). In a three-dimensional (3D) NAND memory device, not only are the memory cells arranged in rows and columns in a horizontal array, but tiers of the horizontal arrays are stacked over one another (e.g., as vertical strings of memory cells) to provide a 3D array of the memory cells. The stack of tiers vertically alternate conductive materials with dielectric materials, with the conductive materials functioning as access lines (e.g., word lines) and gate structures (e.g., control gates) for the memory cells. Pillars comprising channels and tunneling structures extend along and form portions of the memory cells of individual vertical strings of memory cells. A drain end of a string is adjacent one of the top or bottom of the pillar, while a source end of the string is adjacent the other of the top or bottom of the pillar. The drain end is operably connected to a bit line, and the source end is operably connected to a source line. A 3D NAND memory device also includes electrical connections between, e.g., access lines (e.g., word lines) and other conductive structures of the device so that the memory cells of the vertical strings can be selected for writing, reading, and erasing operations.

In the 3D NAND memory device, lateral access to the pillars is achieved by a source contact below the stack of tiers and that extends in a horizontal direction. Forming the source contact causes damage to the pillars, which leads to failure of the 3D NAND memory device.

### BRIEF DESCRIPTION OF THE DRAWINGS

FIGS. 1A and 1B are cross-sectional views of an electronic device in accordance with embodiments of the disclosure, with FIG. 1B being an enlarged view of a portion of the electronic device of FIG. 1A;

FIG. 1C is a top-down view of the electronic device of FIG. 1B taken along the B-B line;

FIGS. 2A and 2B are simplified partial cross-sectional views illustrating a method of forming electronic devices in accordance with embodiments of the disclosure, with FIG. 2B being an enlarged view of a portion of FIG. 2A;

FIG. 3 is a simplified partial cross-sectional view illustrating a method of forming electronic devices in accordance with embodiments of the disclosure;

FIG. 4A is a simplified partial cross-sectional view illustrating a method of forming electronic devices in accordance with embodiments of the disclosure;

FIG. 4B is a top-down view of FIG. 4A taken along the D-D line;

FIG. 5 is a simplified partial cross-sectional view illustrating a method of forming electronic devices in accordance with embodiments of the disclosure;

FIGS. 6A and 6B are cross-sectional views of another electronic device in accordance with embodiments of the disclosure, with FIG. 6B being an enlarged view of a portion of the electronic device of FIG. 6A;

FIG. 6C is a top-down view of the electronic device of FIG. 6B taken along the F-F line;

FIGS. 7A and 7B are simplified partial cross-sectional views illustrating a method of forming electronic devices in accordance with embodiments of the disclosure;

FIG. 8 is a simplified partial cross-sectional view illustrating a method of forming electronic devices in accordance with embodiments of the disclosure;

FIG. 9 is a simplified partial cross-sectional view illustrating a method of forming electronic devices in accordance with embodiments of the disclosure;

FIG. 10 is a partial cutaway, perspective, schematic illustration of a portion of an apparatus including one or more electronic devices in accordance with embodiments of the disclosure;

FIG. 11 is a block diagram of an electronic system including one or more electronic devices in accordance with embodiments of the disclosure;

FIG. 12 is a block diagram of a processor-based system including one or more electronic devices in accordance with embodiments of the disclosure; and

FIG. 13 is a block diagram of an additional processor-based system including one or more electronic devices in accordance with embodiments of the disclosure.

### DETAILED DESCRIPTION

Electronic devices (e.g., apparatus, microelectronic devices) and systems (e.g., electronic systems) according to embodiments of the disclosure include an epitaxial polysilicon material as a source contact. The epitaxial polysilicon material accounts for at least a portion of the source contact. The epitaxial polysilicon material may intervene between polysilicon portions of the source contact or the epitaxial silicon material may account for substantially all of the source contact. The source contact is adjacent to (e.g., on, vertically adjacent to) a source stack and provides lateral access to pillars (e.g., memory pillars) of the electronic device. The source contact provides electrical connection to a channel of the pillars. Methods of forming the electronic devices and systems are also disclosed. The epitaxial polysilicon material of the source contact may be formed at various stages of forming the electronic devices. The epitaxial polysilicon material is used to improve electrical coupling to the pillars and provides a more robust process than forming the electronic devices by conventional techniques. Using the epitaxial polysilicon material may prevent (e.g., substantially prevent) or eliminate shorting between conductive features of the electronic device.

The following description provides specific details, such as material types, material thicknesses, and process conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of an electronic device or a complete process flow for manufacturing the electronic device and the structures described below do not form a complete electronic device. Only those process acts and structures necessary to understand the embodiments described herein are described in detail below. Additional acts to form a complete electronic device may be performed by conventional techniques. Accordingly, only the methods and structures necessary to understand embodiments of the electronic device (e.g., electronic devices, systems, apparatuses) and methods are described herein.

Unless the context indicates otherwise, the materials described herein may be formed by any suitable technique including, but not limited to, spin coating, blanket coating, chemical vapor deposition (“CVD”), atomic layer deposition (“ALD”), plasma enhanced ALD, physical vapor deposition (“PVD”) (e.g., sputtering), or epitaxial growth. Alternatively, the materials may be grown in situ. Depending on the specific material to be formed, the technique for depositing or growing the material may be selected by a person of ordinary skill in the art unless the context indicates otherwise. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

Drawings presented herein are for illustrative purposes only, and are not meant to be actual views of any particular material, component, structure, electronic device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation. The illustrations presented herein are not actual views of any electronic device or system, or any component thereof, but are merely idealized representations, which are employed to describe embodiments of the invention.

As used herein, “and/or” includes any and all combinations of one or more of the associated listed items.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the terms “comprising,” “including,” “containing,” “characterized by,” and grammatical equivalents thereof are inclusive or open-ended terms that do not exclude additional, unrecited elements or method steps, but also include the more restrictive terms “consisting of” and “consisting essentially of” and grammatical equivalents thereof.

As used herein, the term “conductive material” means and includes an electrically conductive material. The conductive material may include, but is not limited to, one or more of a doped polysilicon, undoped polysilicon, a metal, an alloy, a conductive metal oxide, a conductive metal nitride, a conductive metal silicide, and a conductively doped semiconductor material. By way of example only, the conductive material may be one or more of tungsten (W), tungsten nitride (WN_{y}), nickel (Ni), tantalum (Ta), tantalum nitride (TaN_{y}), tantalum silicide (TaSiₓ), platinum (Pt), copper (Cu), silver (Ag), gold (Au), aluminum (Al), molybdenum (Mo), titanium (Ti), titanium nitride (TiN_{y}), titanium silicide (TiSiₓ), titanium silicon nitride (TiSiₓN_{y}), titanium aluminum nitride (TiAlₓN_{y}), molybdenum nitride (MoNₓ), iridium (Ir), iridium oxide (IrO₂), ruthenium (Ru), ruthenium oxide (RuO₂), n-doped polysilicon, p-doped polysilicon, undoped polysilicon, and conductively doped silicon, where x, y, or z are integers or non-integers.

As used herein, the term “configured” refers to a size, shape, material composition, and arrangement of one or more of at least one structure and at least one apparatus facilitating operation of one or more of the structure and the apparatus in a pre-determined way.

As used herein, the phrase “coupled to” refers to structures operably connected with each other, such as electrically connected through a direct ohmic connection or through an indirect connection (e.g., via another structure).

As used herein, the term “dielectric material” means and includes an electrically insulative material. The dielectric material may include, but is not limited to, one or more of an insulative oxide material, an insulative nitride material, an insulative oxynitride material, an insulative carboxynitride material, and/or air. A dielectric oxide material may be an oxide material, a metal oxide material, or a combination thereof. The dielectric oxide material may include, but is not limited to, a silicon oxide (SiOₓ, silicon dioxide (SiO₂)), phosphosilicate glass (PSG), borosilicate glass (BSG), borophosphosilicate glass (BPSG), fluorosilicate glass (FSG), aluminum oxide (AlOₓ), barium oxide, gadolinium oxide (GdOₓ), hafnium oxide (HfOₓ), magnesium oxide (MgOₓ), molybdenum oxide, niobium oxide (NbOₓ), strontium oxide, tantalum oxide (TaOₓ), titanium oxide (TiOₓ), yttrium oxide, zirconium oxide (ZrOₓ), hafnium silicate, a dielectric oxynitride material (e.g., SiOₓN_{y}), a dielectric carbon nitride material (SiCN), a dielectric carboxynitride material (e.g., SiOₓC_{z}N_{y}), a combination thereof, or a combination of one or more of the listed materials with silicon oxide, where values of “x,” “y,” and “z” may be integers or may be non-integers. A dielectric nitride material may include, but is not limited to, silicon nitride. A dielectric oxynitride material may include, but is not limited to, a silicon oxynitride (SiOₓN_{y}). A dielectric carboxynitride material may include, but is not limited to, a silicon carboxynitride (SiOₓC_{z}N_{y}). The dielectric material may be a stoichiometric compound or a non-stoichiometric compound.

As used herein, the term “electronic device” includes, without limitation, a memory device, as well as semiconductor devices which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may, for example, be a 3D electronic device, such as a 3D NAND Flash memory device.

As used herein, the term “epitaxial polysilicon material” refers to a polysilicon material formed by an epitaxial growth process. The epitaxial polysilicon material is distinguishable from polysilicon material formed by other techniques.

As used herein, any relational term, such as “first,” “second,” “top,” “bottom,” “upper,” “lower,” “above,” “beneath,” “side,” “upward,” “downward,” etc., is used for clarity and convenience in understanding the disclosure and accompanying drawings, and does not connote or depend on any specific preference or order, except where the context clearly indicates otherwise. For example, these terms may refer to an orientation of elements of any electronic device or system when utilized in a conventional manner. Furthermore, these terms may refer to an orientation of elements of any electronic device or system as illustrated in the drawings.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, reference to an element as being “on” or “over” another element means and includes the element being directly on top of, adjacent to (e.g., laterally adjacent to, vertically adjacent to), underneath, or in direct contact with the other element. It also includes the element being indirectly on top of, adjacent to (e.g., laterally adjacent to, vertically adjacent to), underneath, or near the other element, with other elements present therebetween. In contrast, when an element is referred to as being “directly on” or “directly adjacent to” another element, no intervening elements are present.

As used herein, the terms “opening” and “slit” mean and include a volume extending through at least one structure or at least one material, leaving a void (e.g., gap) in that at least one structure or at least one material, or a volume extending between structures or materials, leaving a gap between the structures or materials. Unless otherwise described, an “opening” and/or “slit” is not necessarily empty of material. That is, an “opening” and/or “slit” is not necessarily void space. An “opening” and/or “slit” formed in or between structures or materials may comprise structure(s) or material(s) other than that in or between which the opening is formed. And, structure(s) or material(s) “exposed” within an “opening” and/or “slit” is (are) not necessarily in contact with an atmosphere or non-solid environment. Structure(s) or material(s) “exposed” within an “opening” and/or “slit” may be adjacent or in contact with other structure(s) or material(s) that is (are) disposed within the “opening” and/or “slit.”

As used herein, the term “sacrificial,” when used in reference to a material or a structure, means and includes a material or structure that is formed during a fabrication process but at least a portion of which is removed (e.g., substantially removed) prior to completion of the fabrication process. The sacrificial material or sacrificial structure may be present in some portions of the electronic device and absent in other portions of the electronic device.

As used herein, the terms “selectively removable” or “selectively etchable” mean and include a material that exhibits a greater etch rate responsive to exposure to a given etch chemistry and/or process conditions (collectively referred to as etch conditions) relative to another material exposed to the same etch chemistry and/or process conditions. For example, the material may exhibit an etch rate that is at least about five times greater than the etch rate of another material, such as an etch rate of about ten times greater, about twenty times greater, or about forty times greater than the etch rate of the another material. Etch chemistries and process conditions for selectively etching a desired material may be selected by a person of ordinary skill in the art. By way of example only, the etch chemistry may be a phosphoric acid-based etch chemistry, a tetramethylammonium hydroxide (TMAH)-based chemistry, ammonium hydroxide, a hydrogen fluoride (HF)-based etch chemistry, or other halogen-based etch chemistry.

As used herein, the term “substantially” in reference to a given parameter, property, or condition means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “substrate” means and includes a material (e.g., a base material) or construction upon which additional materials or components, such as those within memory cells, are formed. The substrate may be an electronic substrate, a semiconductor substrate, a base semiconductor layer on a supporting structure, an electrode, an electronic substrate having one or more materials, layers, structures, or regions formed thereon, or a semiconductor substrate having one or more materials, layers, structures, or regions formed thereon. The materials on the electronic substrate or semiconductor substrate may include, but are not limited to, semiconductive materials, insulating materials, conductive materials, etc. The substrate may be a conventional silicon substrate or other bulk substrate comprising a layer of semiconductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped. Furthermore, when reference is made to a “substrate” or “base material” in the following description, previous process acts may have been conducted to form materials or structures in or on the substrate or base material.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

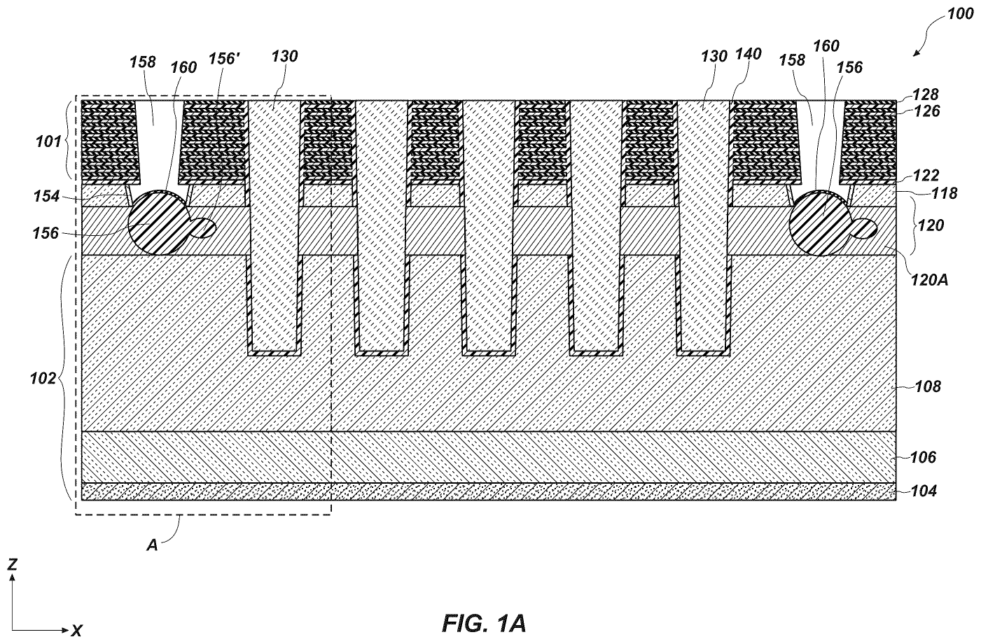

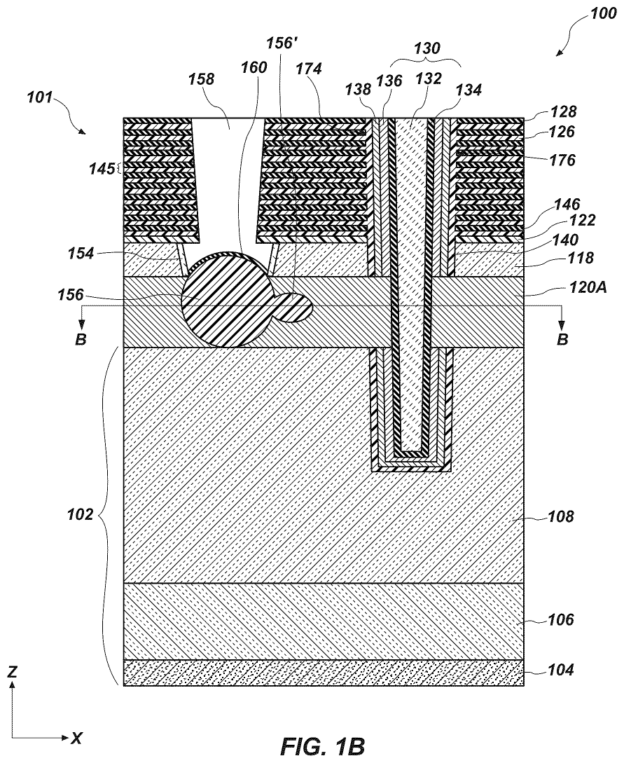

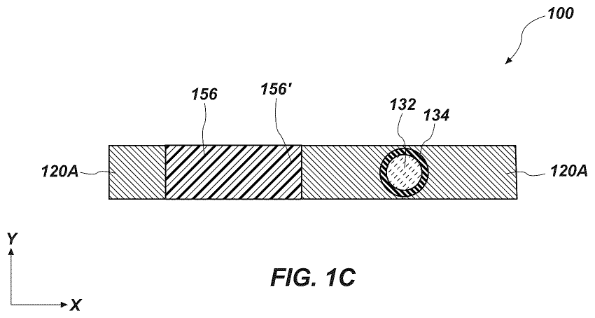

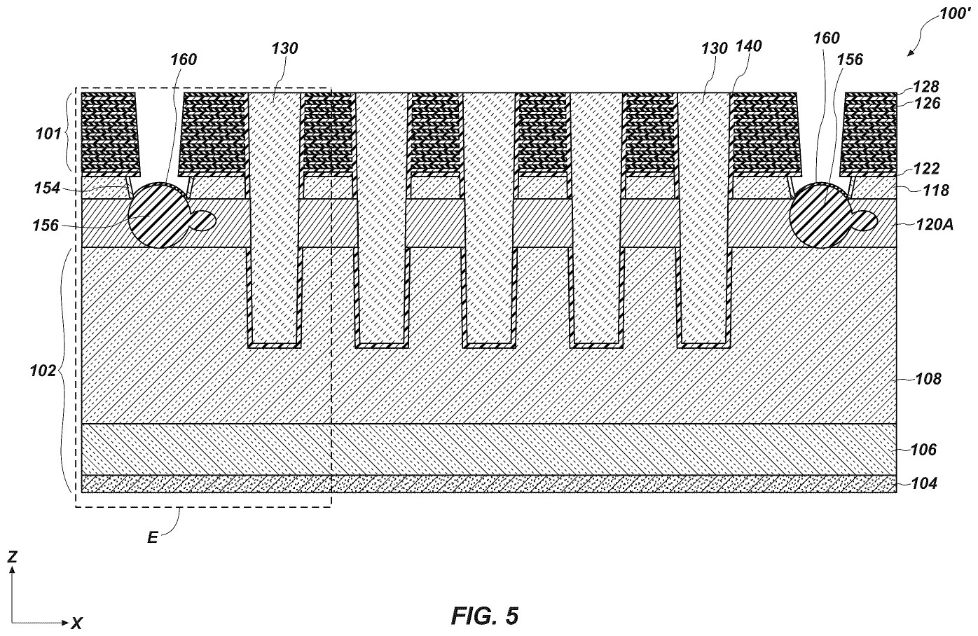

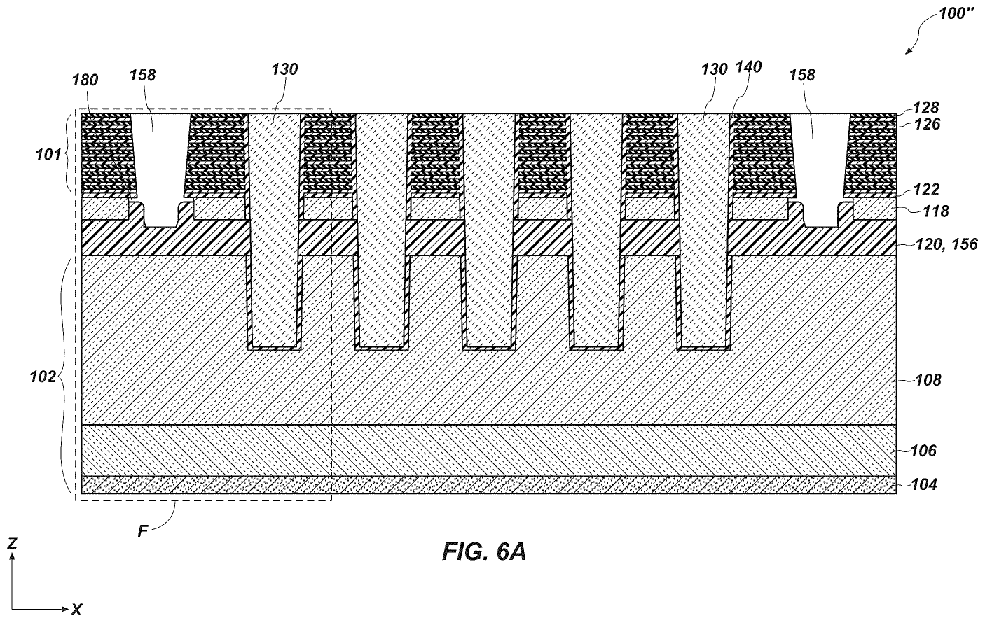

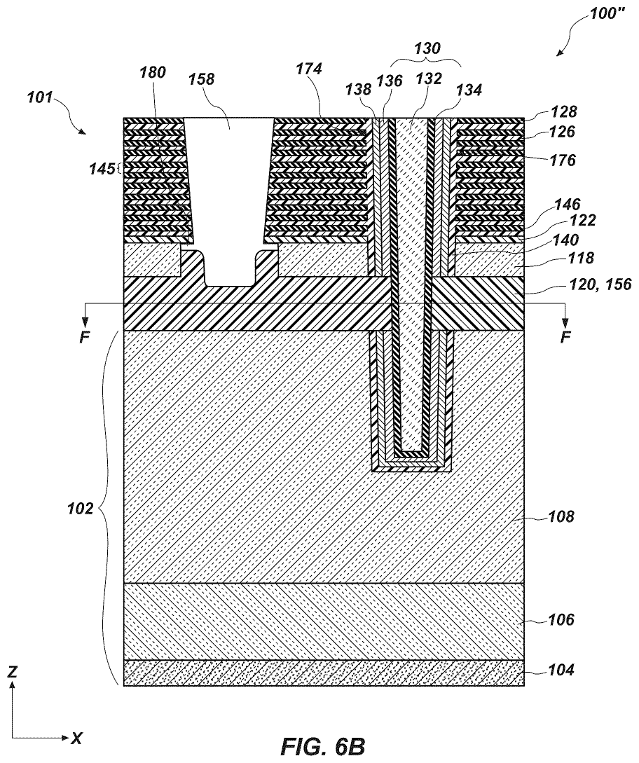

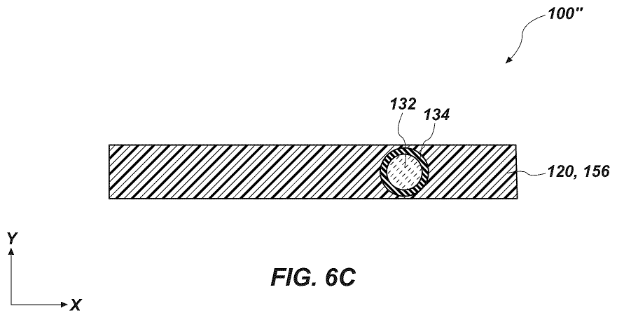

Electronic devices may include the epitaxial polysilicon material between polysilicon portions of the source contact, as shown in FIGS. 1A-5, or the epitaxial polysilicon material may account for substantially all of the source contact, as shown in FIGS. 6A-9.

An electronic device 100 according to embodiments of the disclosure is shown in FIGS. 1A-1C. The electronic device 100 includes a source stack 102 that includes one or more conductive materials, such as a conductive material 104, a source material 106, and a doped semiconductive material 108. The conductive material 104 may be a conductive liner material and is adjacent to (e.g., on, vertically adjacent to) a base material (not shown). The source material 106 is adjacent to (e.g., on, vertically adjacent to) the conductive material 104, and the doped semiconductive material 108 is adjacent to (e.g., on, vertically adjacent to) the source material 106. By way of example only, the conductive material 104 may be formed of titanium nitride, the source material 106 may be formed of tungsten silicide, and the doped semiconductive material 108 may be formed of a doped polysilicon. A source contact 120 that includes one or more portions formed from polysilicon 120A is adjacent to (e.g., on, vertically adjacent to) the source stack 102 and provides lateral access to pillars 130. Epitaxial polysilicon 156 intervenes between laterally adjacent portions of the polysilicon 120A of the source contact 120. In other words, the epitaxial polysilicon 156 accounts for a portion of the source contact 120. As shown in FIGS. 1A-1C, the source contact 120 is formed of and includes the polysilicon 120A and the epitaxial polysilicon 156. A doped dielectric material 118 is adjacent to (e.g., on, vertically adjacent to) the source stack 102. A material of the doped dielectric material 118 is selected to be selectively removable under some etch conditions and to be resistant to removal under other etch conditions. In some embodiments, the doped dielectric material 118 is doped polysilicon, the source contact 120 includes polysilicon 120A and epitaxial polysilicon 156, and the doped semiconductive material 108 is doped polysilicon. A dielectric cap material 122 is adjacent to (e.g., on, vertically adjacent to) the doped dielectric material 118. The dielectric cap material 122 may be formed of a silicon oxide (SiOₓ) material. Relative thickness of the source contact 120 and the doped dielectric material 118 are exaggerated for case of illustrating the electronic device 100.

Tiers 145 of alternating dielectric materials 126 and conductive materials 128 may be adjacent to (e.g., on, vertically adjacent to) the source contact 120. In some embodiments, the dielectric materials 126 are formed of SiOₓ and the conductive materials 128 are formed of tungsten. However, other dielectric materials or conductive materials may be used. Some of the conductive materials 128 of the tiers 145 are configured as so-called “replacement gate” word lines (e.g., word lines formed by the replacement gate or “gate late” process). Other conductive materials 128, such as one or more of the lowermost conductive materials 128, are configured as select gate sources (SGSs) 146 and one or more of the uppermost conductive materials 128 are configured as select gate drains (SGDs). For instance, the one or more conductive materials 128 proximal to the source contact 120 may function as the one or more SGSs 146 and the one or more conductive materials 128 distal to the source contact 120 may function as the one or more SGDs. The tiers 145 form a tier stack 101 adjacent to (e.g., on, vertically adjacent to) the source stack 102, with the source contact 120 laterally separating the tier stack 101 and the source stack 102. The doped dielectric material 118 and the dielectric cap material 122 separate the tier stack 101 from the source contact 120.

The pillars 130 (e.g., memory pillars) extend through the tiers 145, the dielectric cap material 122, the doped dielectric material 118, the source contact 120, and at least partially into the doped semiconductive material 108. While FIG. 1A illustrates the pillars 130 as a single material for convenience, multiple materials may be present, as shown in FIGS. 1B and 1C. The materials of the pillar 130 may be configured and formulated to form memory cells 176 following subsequent processing of the electronic device 100. Cell films of the pillars 130 include a channel 134, a tunnel dielectric material 136, a charge trap material 138, and a charge blocking material 140, which function as tunneling structures of the pillars 130 of the electronic device 100. The pillars 130 also include a fill material 132. The source contact 120 is electrically coupled to (e.g., electrically connected to) the pillars 130, with the source contact 120 contacting (e.g., directly contacting) the channel 134, the tunnel dielectric material 136, the charge trap material 138, and the charge blocking material 140 of the pillars 130. The conductive materials 128 may form strings 174 of the memory cells 176, with individual memory cells 176 located at intersections of the cell films of the pillars 130 and the conductive materials 128 of the tiers 145. The memory cells 176 are laterally adjacent to the conductive materials 128 of the tiers 145.

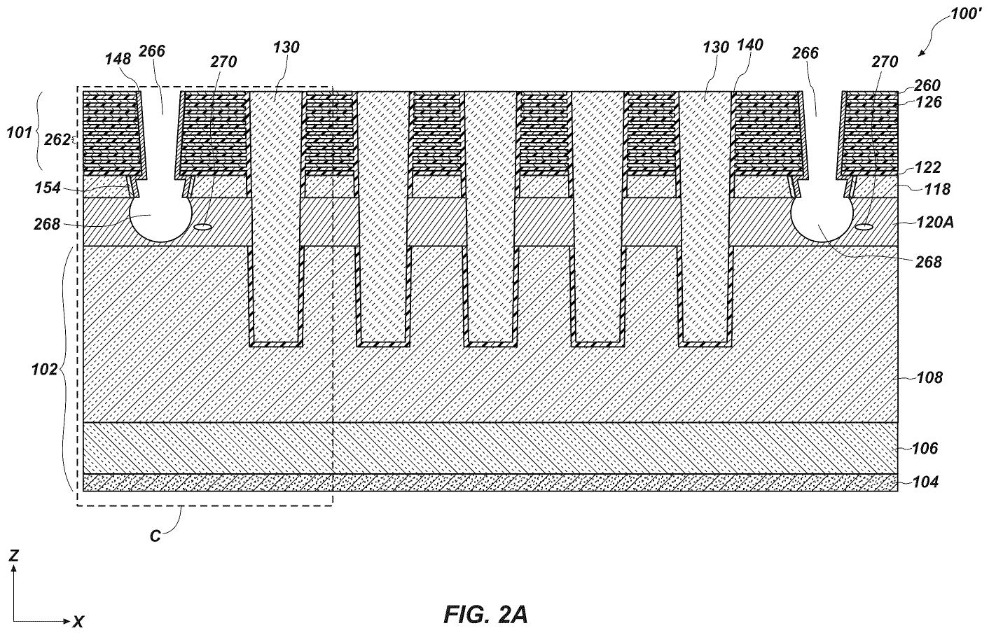

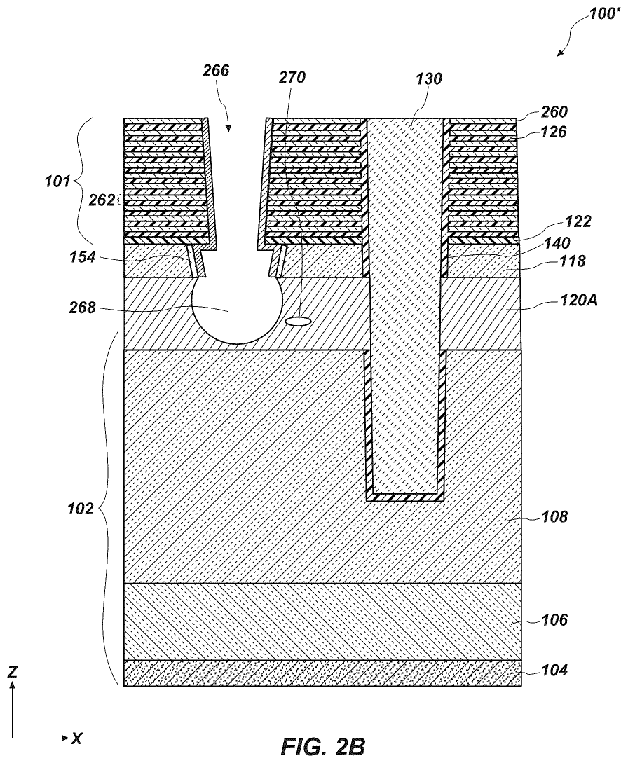

The polysilicon 120A and the epitaxial polysilicon 156 of the source contact 120 may, individually, be doped or undoped. The dopant may be an n-type dopant including, but not limited to, phosphorus, arsenic, antimony, or a combination thereof. A concentration of the dopant in the polysilicon 120A or the epitaxial polysilicon 156 may depend on desired electrical performance properties of the electronic device 100. The epitaxial polysilicon 156 of the source contact 120 may extend into a portion of the doped dielectric material 118 and into at least a portion of the polysilicon 120A of the source contact 120. The epitaxial polysilicon 156 is, thus, in contact with (e.g., in direct contact with) the polysilicon 120A of the source contact 120, polysilicon of the doped dielectric material 118, and polysilicon of the doped semiconductive material 108. A height of the epitaxial polysilicon 156 may be greater than a height of the polysilicon 120A, with the epitaxial polysilicon 156 extending from an upper surface of the doped semiconductive material 108 to above a lower surface of the doped dielectric material 118. An upper portion of the epitaxial polysilicon 156 may be in contact with (e.g., in direct contact with) a fill material 158 (e.g., a slit fill material). Alternatively, an optional dielectric material 160 may intervene between the epitaxial polysilicon 156 and the fill material 158. The epitaxial polysilicon 156 may substantially fill a recess 268 and a void 270 (see FIG. 2A) laterally adjacent to the recess 268. As shown in FIGS. 1A and 1B, the epitaxial polysilicon 156 exhibits a substantially circular or elliptical cross-sectional shape (e.g., a bulbous shape in cross-section), and a portion of the epitaxial polysilicon 156′ may extend in a horizontal direction relative to the epitaxial polysilicon 156.

The fill material 158 may be present in slit 266 (see FIG. 2A), which separates adjacent blocks of the electronic device 100 from one another. The fill material 158 extends in a vertical direction from the epitaxial polysilicon 156 to an upper surface of the tiers 145. The fill material 158 may, for example, be silicon germanium. However, other materials may be used.

A liner 154 (e.g., a slit liner) may be present in the slit between the fill material 158 and the doped dielectric material 118 and the dielectric cap material 122. The slit liner 154 may be formed on sidewalls of the doped dielectric material 118 and the dielectric cap material 122. The slit liner 154 may be a dielectric material including, but not limited to, a silicon oxide, a silicon nitride, silicon oxynitride, aluminum oxide, or hafnium oxide. The fill material 158 may extend in a lateral direction between opposing portions of the slit liner 154 and opposing portions of the tiers 145.

The charge blocking material 140 may be formed of and include a dielectric material. By way of example only, the charge blocking material 140 may be one or more of an oxide (e.g., silicon dioxide), a nitride (silicon nitride), and an oxynitride (silicon oxynitride), or another material. In some embodiments, the charge blocking material 140 is silicon dioxide.

The charge trap material 138 may be formed of and include at least one memory material and/or one or more conductive materials. The charge trap material 138 may be formed of and include one or more of silicon nitride, silicon oxynitride, polysilicon (doped polysilicon), a conductive material (e.g., tungsten, molybdenum, tantalum, titanium, platinum, ruthenium, and alloys thereof, or a metal silicide such as tungsten silicide, molybdenum silicide, tantalum silicide, titanium silicide, nickel silicide, cobalt silicide, or a combination thereof), a semiconductive material (e.g., polycrystalline or amorphous semiconductor material, including at least one elemental semiconductor element and/or including at least one compound semiconductor material, such as conductive nanoparticles (e.g., ruthenium nanoparticles) and/or metal dots). In some embodiments, the charge trap material 138 is silicon nitride.

The tunnel dielectric material 136 may include one or more dielectric materials, such as one or more of a silicon nitride material or a silicon oxide material. In some embodiments, the tunnel dielectric material 136 is a so-called “ONO” structure that includes silicon dioxide, silicon nitride, and silicon dioxide.

The channel 134 may be formed of and include a semiconductive material, a non-silicon channel material, or other channel material. The material of the channel may include, but is not limited to, a polysilicon material (e.g., polycrystalline silicon), a III-V compound semiconductive material, a II-VI compound semiconductive material, an organic semiconductive material, GaAs, InP, GaP, GaN, an oxide semiconductive material, or a combination thereof. In some embodiments, the channel 134 is polysilicon, such as a doped polysilicon. The channel 134 may be configured as a so-called doped hollow channel (DHC) or other configuration. The fill material 132 of the pillars 130 may be a dielectric material, such as silicon dioxide.

To form the electronic device 100, an electronic device structure 100′ is formed, as shown in FIGS. 2A-5. The electronic device structures 100′ in FIGS. 2A-5 illustrate method acts conducted prior to the formation of the electronic device 100 shown in FIGS. 1A-1C. During the fabrication of the electronic device 100, multiple polysilicon materials, such as undoped polysilicon materials and/or doped polysilicon materials, may be present. In FIGS. 1A-5, relative thickness of the source contact 120 and the doped dielectric material 118 are exaggerated for ease of illustrating the electronic device 100, 100′.

As shown in FIGS. 2A and 2B, the materials of the source stack 102 are formed on the base material (not shown). The materials may be formed by conventional techniques. For instance, the conductive material 104, the source material 106, and the doped semiconductive material 108 are sequentially formed on the base material. A source contact sacrificial structure (not shown) may be formed adjacent to the source stack 102 at a location where the source contact 120 is ultimately to be formed. The source contact sacrificial structure may include one or more materials, which are subsequently replaced with polysilicon of the source contact 120. One or more of the materials of the source contact sacrificial structure may include polysilicon. The doped dielectric material 118 may be formed adjacent to the source contact sacrificial structure, and the dielectric cap material 122 may be formed adjacent to the doped dielectric material 118. Tiers 262 of alternating dielectric materials 126 and nitride materials 260 are formed adjacent to (e.g., vertically adjacent to, on) the dielectric cap material 122, with locations of the nitride materials 260 corresponding to subsequent locations of the conductive materials 128 (see FIGS. 1A-1C) of the tiers 145. The pillars 130 may be formed in the electronic device structure 100′, extending through the tiers 262, the dielectric cap material 122, the doped dielectric material 118 and the source contact sacrificial structure, and into the doped semiconductive material 108. The source contact sacrificial structure, doped dielectric material 118, dielectric cap material 122, tiers 262, and pillars 130 may be formed by conventional techniques.

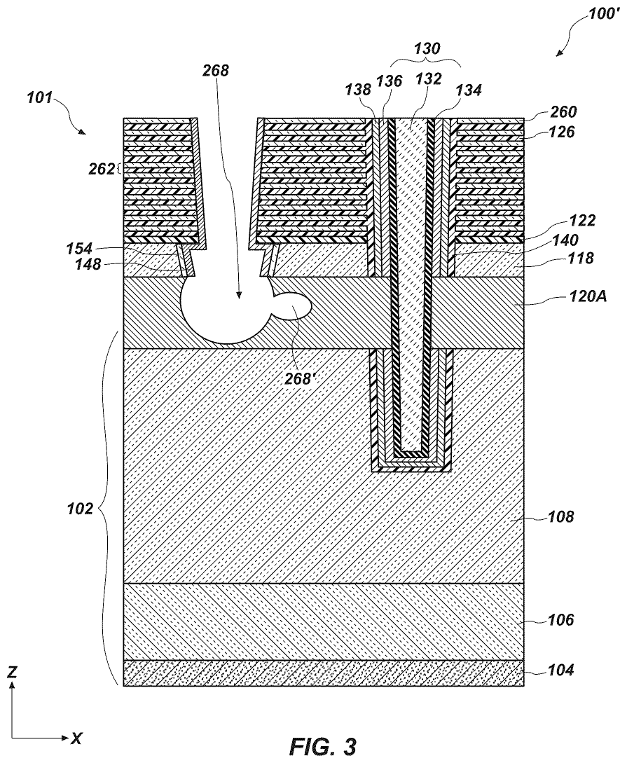

The slit 266 is formed laterally adjacent to the pillars 130 and extends through the tiers 262, the dielectric cap material 122, and the doped dielectric material 118 and partially into the source contact sacrificial structure (not shown). The slit 266 may be a high aspect ratio (HAR) opening, such as having an aspect ratio of greater than about 10:1, greater than about 20:1, greater than about 50:1, greater than about 100:1, or greater than about 150:1. The slit 266 may be formed by conventional techniques. The slit 266 is defined by sidewalls of the tiers 262, sidewalls of the dielectric cap material 122, sidewalls of the doped dielectric material 118, and an exposed upper surface of the source contact sacrificial structure. The slit 266 provides an opening through which materials of the source contact sacrificial structure are removed and the materials of the source contact 120 (e.g., polysilicon and epitaxial polysilicon) are formed, ultimately electrically coupling the source contact 120 to the pillars 130. The source contact sacrificial structure may be removed by conventional techniques and a polysilicon material of the source contact 120 is formed in a lateral opening defined by lower surfaces of the doped dielectric material 118 and upper surfaces of the doped semiconductive material 108. The polysilicon material of the source contact 120 may also be formed in the slit 266. The slit liner 154 is formed on the sidewalls of the doped dielectric material 118 by conventional techniques, such as by one or more conformal deposition processes. A tier liner 148 is formed on the sidewalls of the tiers 262 and the slit liner 154 by conventional techniques. A portion of the polysilicon material within the slit 266 and the source stack 102 may be removed, forming a recess 268 and portions of polysilicon 120A. Portions of the slit liner 154 and the tier liner 148 may also be removed. Removing the polysilicon material and the slit liner 154 may form the recess 268 within the doped dielectric material 118 and the source contact 120. The recess 268 may be formed by, for example, a wet etch process that removes the polysilicon material of the source contact 120 and the slit liner 154 in lateral and vertical directions. The recess 268 may exhibit an elliptical cross-sectional shape, as shown in FIGS. 2A and 2B, and extend between the upper surface of the doped semiconductive material 108 and the lower surface of the doped dielectric material 118. However, the cross-sectional shape may differ depending on the etch conditions (e.g., etch chemistry, temperature, pressure) used. Dimensions (e.g., a depth, a width, and a length) of the recess 268 may be sufficient to contain the epitaxial polysilicon 156. The removal conditions may also form a void 270 between the recess 268 and the pillars 130. The void 270 may be laterally adjacent to the recess 268 and the pillars 130 and be surrounded by the polysilicon 120A of the source contact 120. As a result of subsequent processing acts, the polysilicon 120A between the recess 268 and the void 270 may be removed to form widened recess 268′, as shown in FIG. 3.

Surfaces of polysilicon exposed in the widened recess 268′ may be cleaned, such as to remove native oxide materials, before growing the epitaxial polysilicon 156. The polysilicon surfaces may be cleaned by conventional techniques, such as by using dilute hydrogen fluoride. Alternatively, in situ cleaning of the polysilicon may be conducted, such as by using ammonia (NH₃) and nitrogen trifluoride (NF₃). The NH₃ and NF₃ are introduced and reacted to form an aminosilicate salt, which is removed by heating to a temperature of from about 100° C. to about 150° C., following which the aminosilicate salt is sublimated. Alternatively, a combination of dilute hydrogen fluoride and in situ cleaning may be conducted.

The polysilicon 120A of the source contact 120 may optionally be heated (e.g., annealed) to crystallize the polysilicon 120A before forming the epitaxial polysilicon 156. However, deposition conditions for the polysilicon 120A may be selected so that the polysilicon 120A is substantially crystalline as formed.

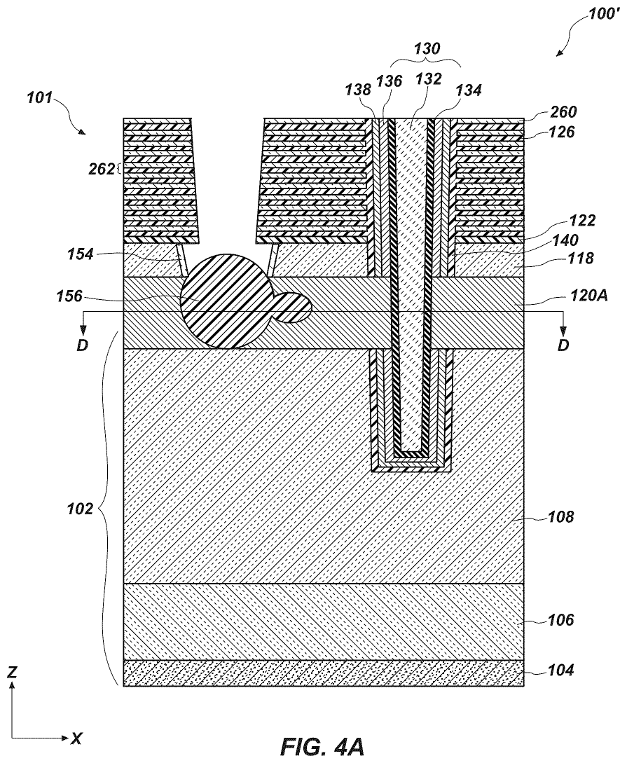

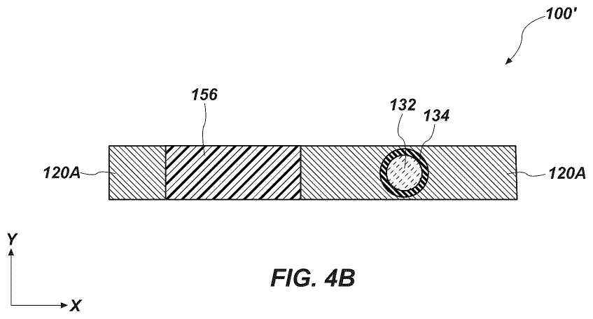

The portion of epitaxial polysilicon 156 is formed after forming the polysilicon 120A and before conducting a replacement gate process. The electronic device 100′ at the process stage shown in FIG. 3 may be placed in a suitable tool, such as a tool including a chamber for conducting the growth of the epitaxial polysilicon 156. While embodiments herein describe using epitaxial polysilicon as a portion of the source contact 120, silicon, silicon germanium (SiGe), or silicon carbide (SiC) may be used in place of the epitaxial polysilicon. In other words, silicon, silicon germanium (SiGe), or silicon carbide (SiC) may be used as the material rather than epitaxial polysilicon. As shown in FIG. 4A, the epitaxial polysilicon 156 is formed in the widened recess 268′, substantially completely filling the widened recess 268′ (e.g., the recess 268 and void 270 as well as any open volume between the recess 268 and the void 270). The epitaxial polysilicon 156 may be grown by a so-called “bottom up” process where the epitaxial polysilicon 156 selectively forms on the bottom and sidewalls of the doped dielectric material 118 and of the polysilicon 120A of the source contact 120. The epitaxial polysilicon 156 may be grown within the widened recess 268′ without substantially growing the epitaxial polysilicon 156 on the tiers 262 of the alternating dielectric materials 126 and nitride materials 260. The epitaxial polysilicon 156 may substantially completely fill the recess 268, the void 270, and the open volume between the recess 268 and void 270, which seals a scam that may be present in the polysilicon 120A. The seam may undesirably form during the deposition of the polysilicon 120A due to geometry and dimensions of an opening in which the polysilicon 120A is formed. The epitaxial polysilicon 156 may extend between laterally adjacent portions of the polysilicon 120A of the source contact 120 and from the lower surface of the polysilicon 120A to above an upper surface of the polysilicon 120A. An upper surface of the epitaxial polysilicon 156 may be relatively higher than a lower surface of the doped dielectric material 118. Since the epitaxial polysilicon 156 fills the widened recess 268′ and extends above the lower surface of the doped dielectric material 118, any seam in the polysilicon 120A is protected. By scaling the seam, the polysilicon 120A may be protected from damage caused by subsequent acts conducted to remove, for example, materials from sidewalls of the tiers 262. In addition, the pillars 130 may be protected from damage. Without the epitaxial polysilicon 156, shorting may occur between the source contact 120 and the channel 134 of the pillars 130. With the epitaxial polysilicon 156 present in the source contact 120, the likelihood of shorting is substantially reduced or eliminated.

The epitaxial polysilicon 156 formed in the widened recess 268′ may be doped or undoped. The dopant may be an n-type dopant including, but not limited to, phosphorus, arsenic, antimony, or a combination thereof. The concentration of the dopant may depend on desired electrical performance properties. If, however, the epitaxial polysilicon 156 is undoped, dopants in the doped semiconductive material 108, the doped dielectric material 118, or the polysilicon material of the source contact 120 may diffuse into the epitaxial polysilicon 156.

The epitaxial polysilicon 156 may be grown by introducing gases into the chamber of the tool. For example, the epitaxial polysilicon 156 may be grown by introducing silicon precursors, dopant precursors, and hydrogen chloride into the chamber so that the gases enter into the slit 266 and widened recess 268′. By way of example only, the silicon precursor may be one or more of silane, disilane, dichlorosilane, trichlorosilane, or a combination thereof. Other halide compounds, such as fluorine compounds, of the silicon precursor may alternatively be used. The dopant precursor may include, but is not limited to phosphine, arsine, stibine, or a combination thereof. However, other dopant precursors may be used. The hydrogen chloride may be used to provide selectivity to the epitaxial polysilicon growth process by removing (e.g., etching) epitaxial polysilicon that forms on sidewalls of the alternating dielectric materials 126 and nitride materials 260 while the epitaxial polysilicon 156 remains on exposed surfaces of the polysilicon of the doped dielectric material 118 and the source contact 120. Relative amounts of the silicon precursor, the dopant precursor, and the hydrogen chloride may be selected depending on the desired extent of doping and a desired growth rate of the epitaxial polysilicon 156. Temperature, pressure, and gas flow rate may be adjusted to achieve the desired amount and growth rate of the epitaxial polysilicon 156 in the widened recess 268′. The hydrogen chloride flow rate may be adjusted to achieve the desired removal of epitaxial polysilicon from the sidewalls of the alternating dielectric materials 126 and nitride materials 260.

The epitaxial polysilicon 156, 156′ formed in the recess 268, widened recess 268′ may be substantially crystalline, with crystallites of the epitaxial polysilicon 156 formed adjacent to the polysilicon 120A and the doped semiconductive material 108. The epitaxial polysilicon 156, 156′ and the polysilicon 120A may be polycrystalline materials. The epitaxial polysilicon 156, 156′ may exhibit a crystal orientation that is substantially similar to the crystal orientation of the polysilicon 120A of the source contact 120. In other words, grains of the epitaxial polysilicon 156, 156′ may be substantially similar in crystal orientation to grains of the polysilicon 120A of the source contact 120 or of the polysilicon of the doped semiconductive material 108. Differences between the epitaxial polysilicon 156, 156′ and the polysilicon 120A may be observed microscopically. The epitaxial polysilicon 156, 156′ may be a substantially crystalline material and the polysilicon 120A or the doped semiconductive material 108 may be a substantially crystalline material. The epitaxial polysilicon 156, 156′ may also include low amounts of halides depending on the silicon precursors used.

After forming the epitaxial polysilicon 156, 156′, the nitride materials 260 of the tiers 262 may be removed, such as by conducting the wet nitride strip process. Conductive materials 128 may be formed in openings between the remaining dielectric materials 126 to form the tiers 145 of alternating dielectric materials 126 and conductive materials 128. Additional processing may be conducted by conventional techniques to form the electronic device 100 from the electronic device structure 100′. The nitride materials 260 may be removed without substantially removing the epitaxial polysilicon 156, 156′ since epitaxial polysilicon 156, 156′ has a lower etch rate than the nitride materials 260 when exposed to the same etch chemistry and/or process conditions. If additional protection of the epitaxial polysilicon 156 and source contact 120 is desired, the optional dielectric material 160 may be formed over exposed surfaces of the epitaxial polysilicon 156 before conducting the wet nitride strip process. Alternatively, a silicide may be formed by exposing the epitaxial polysilicon 156 to tungsten hexafluoride or the exposed surfaces of the epitaxial polysilicon 156 may be selectively oxidized. The fill material 158 may subsequently be formed over the epitaxial polysilicon 156, substantially completely filling the slit 266.

As shown in FIGS. 6A-6C, the epitaxial polysilicon 156 may account for substantially all of the source contact 120 in electronic device 100″. In comparison to the electronic device 100, the electronic device 100″ differs in the extent (e.g., amount) of epitaxial polysilicon 156 in the source contact 120. The epitaxial polysilicon 156 may extend from the upper surface of the doped semiconductive material 108 to the lower surface of the doped dielectric material 118 in areas of the electronic device 100″ proximate to the pillars 130. In areas of the electronic device 100″ proximate to the fill material 158, the epitaxial polysilicon 156 may extend from the upper surface of the doped semiconductive material 108 to above the lower surface of the fill material 158. The epitaxial polysilicon 156 is in direct contact with the underlying doped semiconductive material 108 and the overlying doped dielectric material 118. The epitaxial polysilicon 156 is also in direct contact with the pillars 130. As shown most clearly in FIG. 6C, the epitaxial polysilicon 156 surrounds the pillars 130 and laterally extends between regions below the fill material 158. Little to no polysilicon is present in the source contact 120 of the electronic device 100″. Therefore, the source contact 120 is substantially free of polysilicon. Other features of the electronic device 100″ are similar to those of electronic device 100.

The epitaxial polysilicon 156 is also in direct contact with a portion of sidewalls of the doped dielectric material 118. However, the epitaxial polysilicon 156 is not in direct contact along an entire height of the doped dielectric material 118. In other words, the epitaxial polysilicon 156 directly contacts only a portion of the doped dielectric material 118, such as along the sidewalls. A gap 180 is present between the upper surface of the epitaxial polysilicon 156 and a lowermost surface of the tier stack 101. The fill material 158 is present in the gap 180 and directly contacts the sidewalls of the doped dielectric material 118 above the epitaxial polysilicon 156 and the lowermost surface of the tier stack 101.

The epitaxial polysilicon 156 of the source contact 120 may be doped or undoped. In some embodiments, the epitaxial polysilicon 156 is a doped polysilicon, such as phosphorus doped polysilicon. However other n-type dopants, such as arsenic, antimony, a combination of arsenic and antimony, or a combination with phosphorus, may be used. The concentration of the dopant to be achieved in the source contact 120 may depend on desired electrical performance properties.

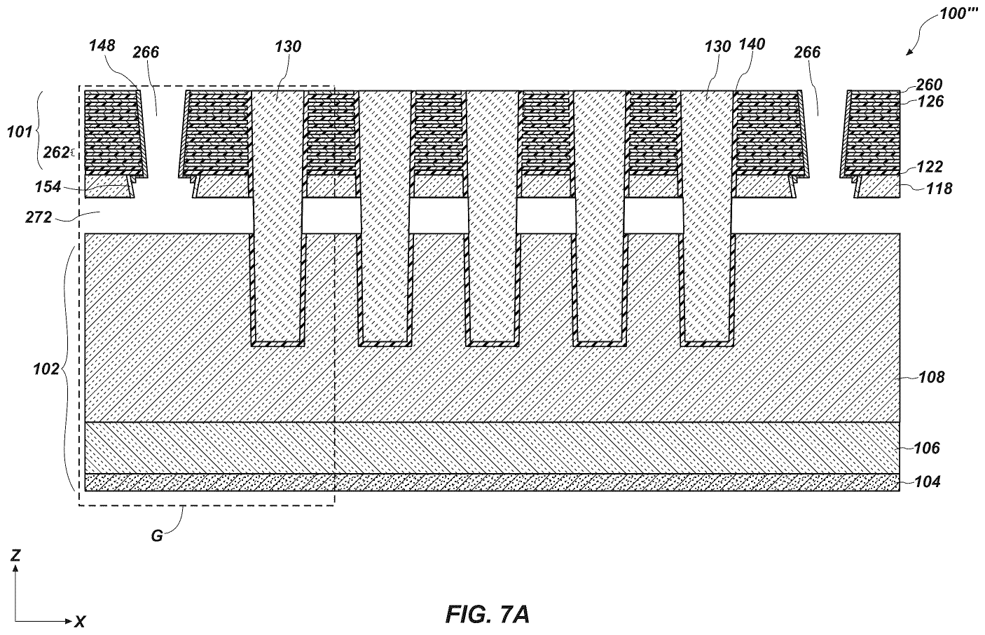

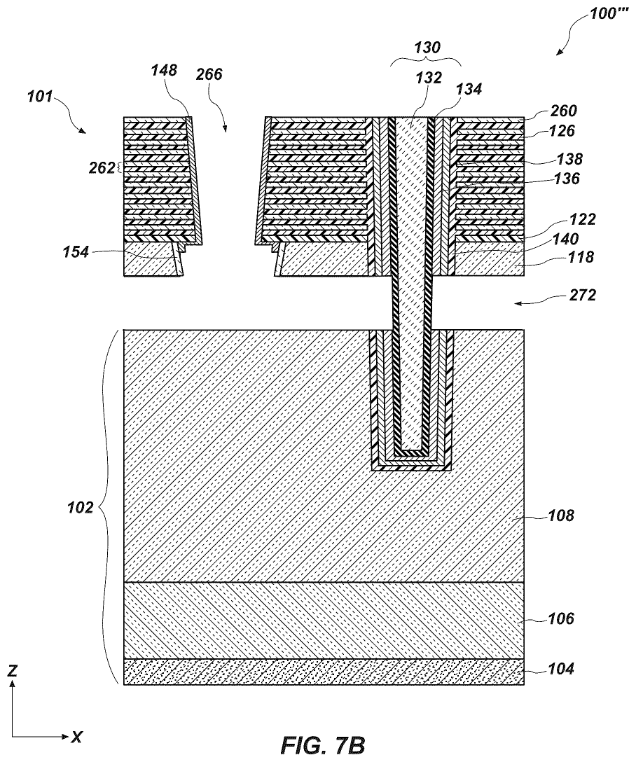

Portions of forming the electronic device 100″ are similar to forming electronic device 100, 100′ except that the epitaxial polysilicon 156 is formed (e.g., grown) to substantially fill source contact opening 272, as shown in FIGS. 7A and 7B. In electronic device 100″, the source contact opening 272 is formed between the doped semiconductive material 108 and the doped dielectric material 118 by removing a source contact sacrificial structure (not shown). The source contact sacrificial structure is formed and removed by conventional techniques. Forming the source contact opening 272 exposes materials of the pillars 130, such as the channels 134, so that electrical communication between the source contact 120 and pillars 130 may occur. As described above, exposed polysilicon surfaces may be cleaned, such as to remove native oxide materials, before growing the epitaxial polysilicon 156. The polysilicon surfaces may be cleaned by conventional techniques, such as by using dilute hydrogen fluoride. Alternatively, in situ cleaning of the polysilicon may be conducted, such as by using ammonia (NH₃) and nitrogen trifluoride (NF₃). The NH₃ and NF₃ are introduced and reacted to form an aminosilicate salt, which is removed by heating to a temperature of from about 100° C. to about 150° C., following which the aminosilicate salt is sublimated. Alternatively, a combination of dilute hydrogen fluoride and in situ cleaning may be conducted.

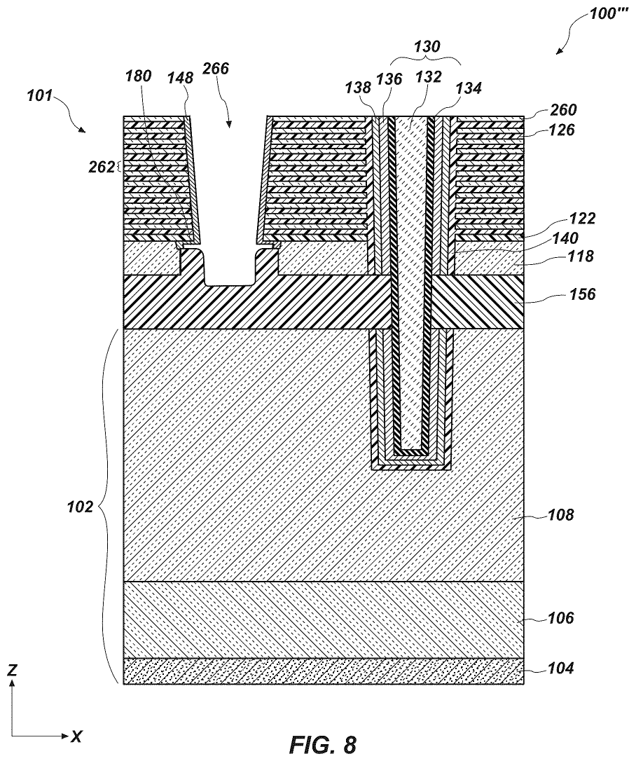

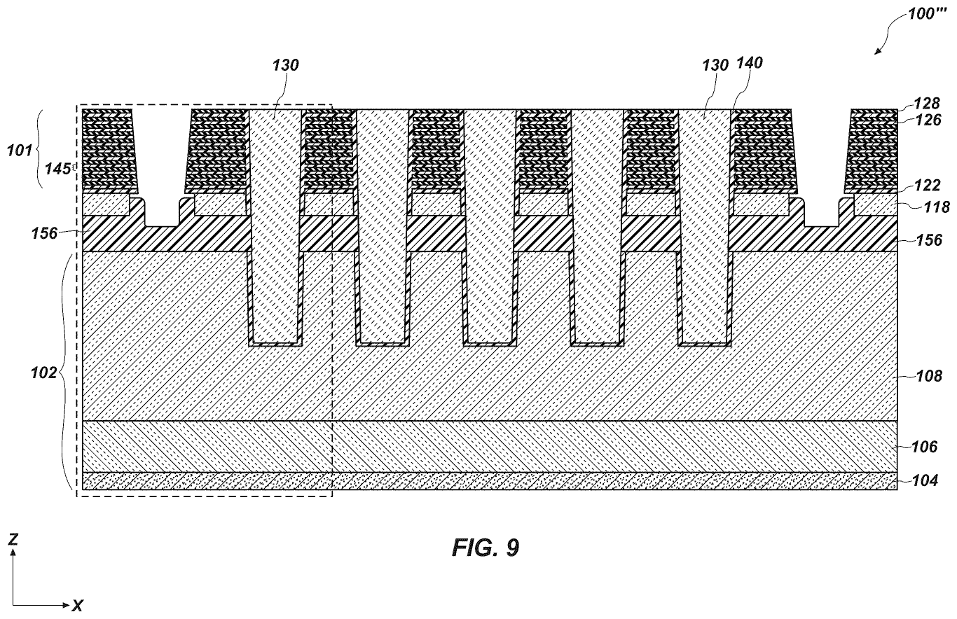

As shown in FIGS. 8 and 9, the epitaxial polysilicon 156 is formed to substantially completely fill the source contact opening 272. The epitaxial polysilicon 156 is formed at an earlier process stage than the formation of the epitaxial polysilicon 156 in the electronic device 100 shown in FIGS. 1A-5. The epitaxial polysilicon 156 is formed after forming the source contact opening 272 and before conducting the replacement gate process. Other features of the electronic device 100″ may be similar to those of electronic device 100. Forming other features of the electronic device 100′″ may be similar to forming those of electronic device 100′. A slit liner 154 and tier liner 148 may be formed on sidewalls of the tiers 262 by conventional techniques.

The epitaxial polysilicon 156 is formed in the source contact opening 272 and extends from the upper surface of doped semiconductive material 108 to the lower surface of doped dielectric material 118 in areas of the electronic device 100″ proximate to the pillars 130. In areas of the electronic device 100′″ proximate to the slit 266, the epitaxial polysilicon 156 also extends from the upper surface of doped semiconductive material 108 to the lower surface of the fill material 158. However, the epitaxial polysilicon 156 may also extend into the slit 266, with the upper surface of the epitaxial polysilicon 156 in the slit 266 being concave or concave. However, the epitaxial polysilicon 156 does not substantially form on sidewalls of the tiers 262 or the tier liner 148. The epitaxial polysilicon 156 grows from the upper surface of the doped semiconductive material 108 until the source contact opening 272 is substantially completely filled. However, the epitaxial polysilicon 156 is not in contact with a portion of the sidewalls of the doped dielectric material 118. While FIG. 8 shows the epitaxial polysilicon 156 in the slit 266 as exhibiting sloped sidewalls, other cross-sectional profiles of the epitaxial polysilicon 156 are possible. In other words, the epitaxial polysilicon 156 directly contacts only a portion of the sidewalls of the doped dielectric material 118. The cross-sectional profile of the epitaxial polysilicon 156 may be achieved by tailoring the deposition of epitaxial polysilicon 156 in the source contact opening 272 and the removal of epitaxial polysilicon 156 from the tier 262 sidewalls. A portion of the sidewalls of the doped dielectric material 118 remains free of the epitaxial polysilicon 156, forming a gap 180 between the upper surface of the epitaxial polysilicon 156 and the slit liner 154. The fill material 158 directly contacts the other sidewalls of the doped dielectric material 118 or slit liner 154.

The epitaxial polysilicon 156 may be formed by a CVD process, such as a low pressure CVD process. The silicon precursors, dopant precursors, and hydrogen chloride are introduced into the chamber containing the electronic device 100″ ′, such as into the source contact opening 272 as described above for FIGS. 2-5. The flow rates of the gases, concentration of the gases, and temperature of the process may be adjusted to selectively form the epitaxial polysilicon 156 in the source contact opening 272 without substantially forming the epitaxial polysilicon 156 on the sidewalls of the tiers 262 and slit liner 154. The epitaxial polysilicon 156 forms selectively on the polysilicon of the doped semiconductive material 108. The selective deposition of the epitaxial polysilicon 156 may also be due to a thermodynamic potential difference between polysilicon materials of the electronic device 100″′ and the tier liner 148. By conducting the CVD process for an appropriate amount of time, the epitaxial polysilicon 156 may substantially completely fill the source contact opening 272. If epitaxial polysilicon 156 forms on the sidewalls of the tiers 262, the hydrogen chloride may etch and remove the epitaxial polysilicon 156. Without using hydrogen chloride during the epitaxial polysilicon growth process, the epitaxial polysilicon 156 may undesirably form on the sidewalls of the tiers 262.

The flow rate and concentration of the silicon precursor and the dopant precursor may be selected to achieve the desired dopant concentration in the source contact 120 of the electronic device 100″. Without being bound by theory, it is believed that the dopant, such as phosphorus, segregates to the grain boundary during the growth of the epitaxial polysilicon 156, which leads to in situ crystallization of the silicon material. Therefore, no additional acts are conducted to convert the silicon material from amorphous (e.g., as—formed) to crystalline (e.g., polycrystalline). The epitaxial polysilicon 156 formed according to embodiments of the disclosure is formed in situ as polycrystalline. If, however, the epitaxial polysilicon 156 is not sufficiently polycrystalline, optional anneal acts may be conducted to further crystallize the epitaxial polysilicon 156.

The hydrogen chloride may be used to provide selectivity to the epitaxial polysilicon growth process by removing (e.g., etching) epitaxial polysilicon that forms on sidewalls of the alternating dielectric materials 126 and nitride materials 260 while the epitaxial polysilicon 156 remains on the surfaces of the polysilicon of the doped dielectric material 118 and the source contact 120. By introducing sufficient hydrogen chloride into the chamber to create a supersaturated environment, the epitaxial polysilicon 156 growth process may be conducted at a low pressure. In addition, the supersaturated hydrogen chloride environment may provide an etch rate difference between the epitaxial polysilicon 156 and the polysilicon of the doped dielectric material 118 and the doped semiconductive material 108. The hydrogen chloride may etch any epitaxial polysilicon 156 located on the sidewalls of the tiers 262 during the. By keeping the sidewalls of the tiers 262 relatively free of epitaxial polysilicon 156 during the epitaxial polysilicon growth process, a subsequent etch process is eliminated in methods according to embodiments of the disclosure compared to conventional processes of forming the source contact 120 from polysilicon where a subsequent etch process is required to remove polysilicon from the tiers 262 sidewalls.

Relative amounts of the silicon precursor, the dopant precursor, and the hydrogen chloride may be selected depending on the extent of doping and a desired growth rate of the epitaxial polysilicon 156. In addition, temperature, pressure, and precursor flow rate may be adjusted to achieve the desired amount and growth rate of the epitaxial polysilicon 156 in the source contact opening 272. The growth process may be conducted at a temperature of greater than or equal to about 500° C., such as from greater than or equal to from about 500° C. to about 750° C., from about 550° C. to about 750° C., from about 600° C. to about 750° C., from about 600° C. to about 700° C., from about 630° C. to about 680° C., or from about 640° C. to about 680° C.

The hydrogen chloride flow rate may be tailored to achieve the desired removal of epitaxial polysilicon from the sidewalls of the alternating dielectric materials 126 and nitride materials 260. A relatively high flow rate of the hydrogen chloride may form the epitaxial polysilicon 156 more slowly because more epitaxial polysilicon 156 is removed than formed. By way of example only, the hydrogen chloride may be introduced at a flow rate of from about 50 standard cubic centimeters per minute (sccm) to about 200 sccm.

The epitaxial polysilicon 156 formed according to embodiments of the disclosure may be formed in situ as polycrystalline. If, however, the epitaxial polysilicon 156 is not sufficiently polycrystalline, optional anneal acts may be conducted to further crystallize the epitaxial polysilicon 156. The epitaxial polysilicon 156 of the source contact 120 may optionally be heated (e.g., annealed) to crystallize the epitaxial polysilicon 156 if deposition conditions do not form the epitaxial polysilicon 156 substantially crystalline as formed. Additional process acts (e.g., wash acts, clean acts) may be conducted before forming the electronic device 100″ from the electronic device 100′−.

After forming the source contact 120 from epitaxial polysilicon 156, the source contact 120 may optionally be protected by one or more material layers. If, for instance, additional protection of the epitaxial polysilicon 156 (e.g., the source contact 120) is desired, the optional dielectric material 160 may be formed over exposed surfaces of the epitaxial polysilicon 156 before conducting the wet nitride strip process. Alternatively, a silicide may be formed by exposing the epitaxial polysilicon 156 to tungsten hexafluoride or the exposed surfaces of the epitaxial polysilicon 156 may be selectively oxidized.

The nitride materials 260 may be removed by the wet nitride strip process, following which the conductive materials 128 are formed in openings between vertically adjacent dielectric materials 126 as previously described. The remainder of the slit 266 may be filled with the fill material 158, which also forms in the gap 180. The fill material 158 therefore separates the tier stack 101 from the epitaxial polysilicon 156 in areas proximal to the fill material 158.

By using the epitaxial polysilicon 156 as the source contact 120, the likelihood of process acts (e.g., etch acts, clean acts) undesirably attacking a polysilicon seam may be reduced. Therefore, the methods according to embodiments of the disclosure may be more robust than conventional methods of forming a source contact. In the formation of conventional electronic devices where the source contact is formed from polysilicon, the wet nitride strip may undesirably remove portions of the polysilicon adjacent to the pillars 130, exposing and disconnecting materials of the pillars 130, which may cause the conventional electronic device to fail. The epitaxial polysilicon 156 proximal to the fill material 158 in the electronic device 100″ may include a cross-sectional profile with sloped sidewalls that extend vertically along only a portion of the sidewalls of the doped dielectric material 118, as shown in FIGS. 6A and 6B, with the epitaxial polysilicon 156 separated from the tiers 145 in a vertical direction by the fill material 158. In the formation of conventional electronic devices where the source contact is formed from polysilicon, the cross-sectional profile of the polysilicon in a similar location may include a larger cavity having a bulbous shape.

Accordingly, disclosed is an electronic device that comprises a source stack comprising one or more conductive materials, a source contact adjacent to the source stack, tiers of alternating conductive materials and dielectric materials adjacent to the source contact, and pillars extending through the tiers and the source contact and into the source stack. At least a portion of the source contact comprises an epitaxial polysilicon material.

Accordingly, disclosed is a method of forming an electronic device that comprises forming a source stack adjacent to a base material and forming a source contact adjacent to the source stack. A doped dielectric material is formed adjacent to the source contact and tiers of alternating nitride materials and dielectric materials are formed adjacent to the doped dielectric material. A slit is formed through the tiers of alternating nitride materials and dielectric materials and into the source contact. The nitride materials in the tiers are replaced with conductive materials and a fill material is formed in the slit, the fill material adjacent to the source contact.

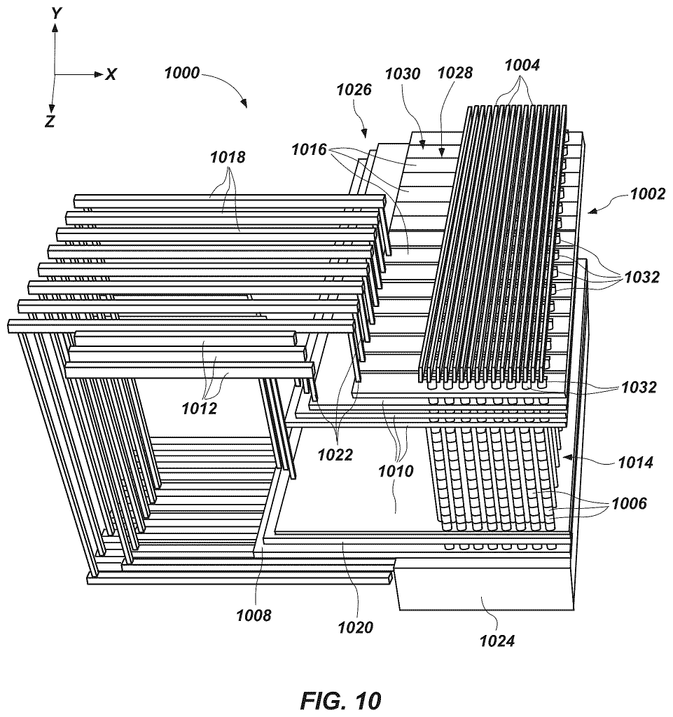

An apparatus 1000 (e.g., a memory device) that includes one or more of the electronic devices 100, 100″ according to embodiments of the disclosure is shown in FIG. 10. Electronic device 1002 may be substantially similar to the embodiments of the electronic device 100, 100″ described above. By way of example only, the memory device may be a 3D NAND Flash memory device, such as a multideck 3D NAND Flash memory device. As illustrated in FIG. 10, the electronic device 1002 may include a staircase structure 1026 defining contact regions for connecting access lines (e.g., word lines) 1012 to conductive tiers 1010 (e.g., conductive regions, conductive materials of tiers). The electronic device 1002 may include pillars 130 with strings 1014 (e.g., strings of memory cells) that are coupled to each other in series. The pillars 130 with the strings 1014 may extend at least somewhat vertically (e.g., in the Z-direction) and orthogonally relative to the conductive tiers 1010, relative to data lines 1004, relative to a source tier 1008 (e.g., within one or more base materials under the source stack 102 (see FIGS. 1A, 1B, 6A, 6B)), relative to the access lines 1012, relative to first select gates 1016 (e.g., upper select gates, drain select gates (SGDs)), relative to select lines 1018, and/or relative to second select gates 1020 (e.g., SGS 146). The first select gates 1016 may be horizontally divided (e.g., in the X-direction) into multiple blocks 1030 by slits 1028.

Vertical conductive contacts 1022 may electrically couple components to each other, as illustrated. For example, the select lines 1018 may be electrically coupled to the first select gates 1016, and the access lines 1012 may be electrically coupled to the conductive tiers 1010. The apparatus 1000 may also include a control unit 1024 positioned under the memory array, which may include at least one of string driver circuitry, pass gates, circuitry for selecting gates, circuitry for selecting conductive lines (e.g., the data lines 1004, the access lines 1012), circuitry for amplifying signals, and circuitry for sensing signals. The control unit 1024 may be electrically coupled to the data lines 1004, the source tier 1008, the access lines 1012, the first select gates 1016, and/or the second select gates 1020, for example. In some embodiments, the control unit 1024 includes CMOS (complementary metal-oxide-semiconductor) circuitry. In such embodiments, the control unit 1024 may be characterized as having a so-called “CMOS under Array” (CuA) configuration.

The first select gates 1016 may extend horizontally in a first direction (e.g., the Y-direction) and may be coupled to respective first groups of strings 1014 of memory cells 1006 at a first end (e.g., an upper end) of the strings 1014. The second select gate 1020 may be formed in a substantially planar configuration and may be coupled to the strings 1014 at a second, opposite end (e.g., a lower end) of the strings 1014 of memory cells 1006.

The data lines 1004 (e.g., bit lines) may extend horizontally in a second direction (e.g., in the X-direction) that is at an angle (e.g., perpendicular) to the first direction in which the first select gates 1016 extend. The data lines 1004 may be coupled to respective second groups of the strings 1014 at the first end (e.g., the upper end) of the strings 1014. A first group of strings 1014 coupled to a respective first select gate 1016 may share a particular string 1014 with a second group of strings 1014 coupled to a respective data line 1004. Thus, a particular string 1014 may be selected at an intersection of a particular first select gate 1016 and a particular data line 1004. Accordingly, the first select gates 1016 may be used for selecting memory cells 1006 of the strings 1014 of memory cells 1006.

The conductive tiers 1010 (e.g., word lines, conductive liner materials) may extend in respective horizontal planes. The conductive tiers 1010 may be stacked vertically, such that each conductive tier 1010 is coupled to all of the strings 1014 of memory cells 1006, and the strings 1014 of the memory cells 1006 extend vertically through the stack of conductive tiers 1010. The conductive tiers 1010 may be coupled to or may function as control gates of the memory cells 1006 to which the conductive tiers 1010 are coupled. Each conductive tier 1010 may be coupled to one memory cell 1006 of a particular string 1014 of memory cells 1006. The first select gates 1016 and the second select gates 1020 may operate to select a particular string 1014 of the memory cells 1006 between a particular data line 1004 and the source tier 1008. Thus, a particular memory cell 1006 may be selected and electrically coupled to a data line 1004 by operation of (e.g., by selecting) the appropriate first select gate 1016, second select gate 1020, and conductive tier 1010 that are coupled to the particular memory cell 1006.

The staircase structure 1026 may be configured to provide electrical connection between the access lines 1012 and the conductive materials of the tiers 1010 through the vertical conductive contacts 1022. In other words, a particular level of the conductive tiers 1010 may be selected via one of the access lines 1012 that is in electrical communication with a respective one of the vertical conductive contacts 1022 in electrical communication with the particular conductive tier 1010. The data lines 1004 may be electrically coupled to the strings 1014 through conductive structures 1032 (e.g., conductive contacts).

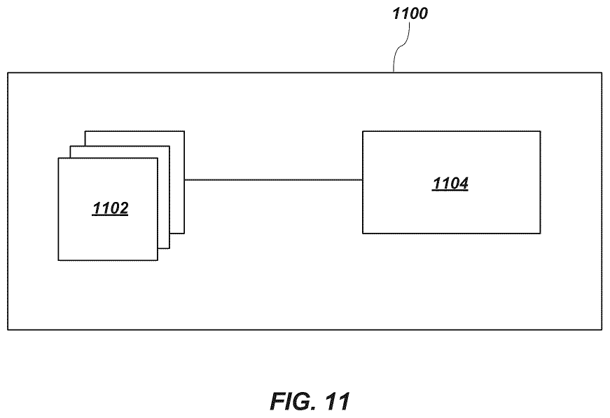

The apparatus 1000 may be used in embodiments of electronic systems of the disclosure. FIG. 11 is a block diagram of an electronic system 1100, in accordance with embodiments of the disclosure. The electronic system 1100 includes, for example, a computer or computer hardware component, a server or other networking hardware component, a cellular telephone, a digital camera, a personal digital assistant (PDA), a portable media (e.g., music) player, a Wi-Fi or cellular-enabled tablet (e.g., an iPAD® or SURFACE® tablet, an electronic book, a navigation device), etc. The electronic system 1100 includes at least one memory device 1102 (e.g., a 3D NAND memory device) that includes, for example, one or more electronic devices 100, 100″. The electronic system 1100 may further include at least one electronic signal processor device 1104 (e.g., a microprocessor). The electronic signal processor device 1104 may, optionally, include one or more electronic devices 100, 100″.

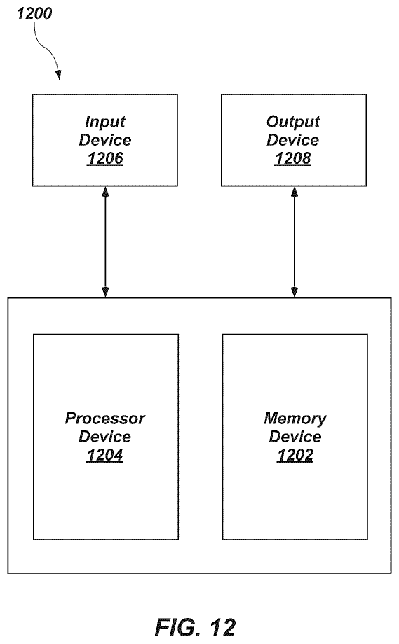

A processor-based system 1200 (e.g., an electronic processor-based system 1200), shown in FIG. 12, includes one or more input devices 1206 for inputting information into the processor-based system 1200 by a user, such as, for example, a mouse or other pointing device, a keyboard, a touchpad, a button, or a control panel. The processor-based system 1200 may further include one or more output devices 1208 for outputting information (e.g., visual or audio output) to a user such as, for example, a monitor, a display, a printer, an audio output jack, a speaker, etc. In some embodiments, the input device 1206 and the output device 1208 may comprise a single touchscreen device that can be used both to input information into the processor-based system 1200 and to output visual information to a user. The input device 1206 and the output device 1208 may communicate electrically with one or more of the memory device 1202 and the electronic signal processor device 1204. The memory device 1202 and the electronic signal processor device 1204 may include one or more of the electronic devices 100, 100″.

Accordingly, disclosed is an electronic system comprising an input device, an output device, a processor device operably coupled to the input device and to the output device, and one or more memory devices operably coupled to the processor device. The one or more memory devices comprises a source contact comprising at least a portion of epitaxial polysilicon adjacent to a source contact. A doped dielectric material is between the source stack and tiers of alternating conductive materials and dielectric materials adjacent to the doped dielectric material. Memory pillars extend through the tiers of alternating conductive materials and dielectric materials and into the source stack, the source contact operably coupled to the memory pillars.

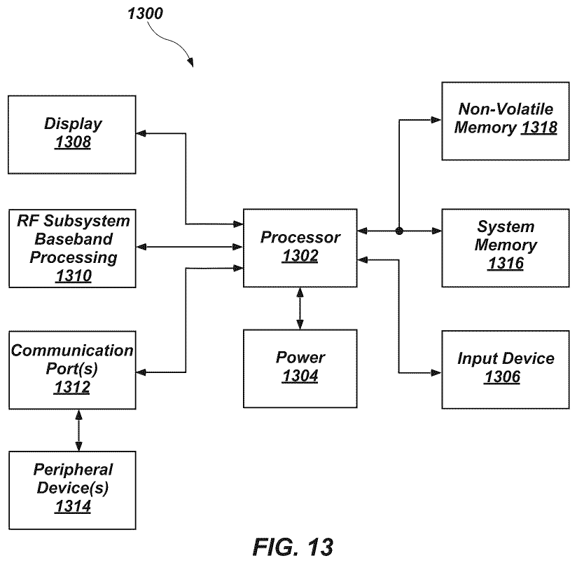

With reference to FIG. 13, shown is a block diagram of an additional processor-based system 1300 (e.g., an electronic processor-based system 1300). The processor-based system 1300 may include various electronic devices 100, 100″ and apparatus 1000 manufactured in accordance with embodiments of the disclosure. The processor-based system 1300 may be any of a variety of types, such as a computer, a pager, a cellular phone, a personal organizer, a control circuit, or another electronic device. The processor-based system 1300 may include one or more processors 1302, such as a microprocessor, to control the processing of system functions and requests in the processor-based system 1300. The processor 1302 and other subcomponents of the processor-based system 1300 may include electronic devices 100, 100″ and apparatus 1000 manufactured in accordance with embodiments of the disclosure.

The processor-based system 1300 may include a power supply 1304 in operable communication with the processor 1302. For example, if the processor-based system 1300 is a portable system, the power supply 1304 may include one or more of a fuel cell, a power scavenging device, permanent batteries, replaceable batteries, and/or rechargeable batteries. The power supply 1304 may also include an AC adapter if, for example, the processor-based system 1300 may be plugged into a wall outlet. The power supply 1304 may also include a DC adapter such that the processor-based system 1300 may be plugged into a vehicle cigarette lighter or a vehicle power port, for example.

Various other devices may be coupled to the processor 1302 depending on the functions that the processor-based system 1300 performs. For example, a user interface may be coupled to the processor 1302. The user interface may include one or more input devices 1306, such as buttons, switches, a keyboard, a light pen, a mouse, a digitizer and stylus, a touch screen, a voice recognition system, a microphone, or a combination thereof. A display 1308 may also be coupled to the processor 1302. The display 1308 may include an LCD display, an SED display, a CRT display, a DLP display, a plasma display, an OLED display, an LED display, a three-dimensional projection, an audio display, or a combination thereof. Furthermore, an RF subsystem/baseband processor 1310 may also be coupled to the processor 1302. The RF subsystem/baseband processor 1310 may include an antenna that is coupled to an RF receiver and to an RF transmitter. A communication port 1312, or more than one communication port 1312, may also be coupled to the processor 1302. The communication port 1312 may be adapted to be coupled to one or more peripheral devices 1314 (e.g., a modem, a printer, a computer, a scanner, a camera) and/or to a network (e.g., a local area network (LAN), a remote area network, an intranet, or the Internet).

The processor 1302 may control the processor-based system 1300 by implementing software programs stored in the memory (e.g., system memory 1316). The software programs may include an operating system, database software, drafting software, word processing software, media editing software, and/or media-playing software, for example. The memory is operably coupled to the processor 1302 to store and facilitate execution of various programs. For example, the processor 1302 may be coupled to system memory 1316, which may include one or more of spin torque transfer magnetic random access memory (STT-MRAM), magnetic random access memory (MRAM), dynamic random access memory (DRAM), static random access memory (SRAM), racetrack memory, and/or other known memory types. The system memory 1316 may include volatile memory, nonvolatile memory, or a combination thereof. The system memory 1316 is typically large so it can store dynamically loaded applications and data. The system memory 1316 may include one or more apparatus 1000 and one or more electronic devices 100, 100″ according to embodiments of the disclosure.

The processor 1302 may also be coupled to non-volatile memory 1318, which is not to suggest that system memory 1316 is necessarily volatile. The non-volatile memory 1318 may include one or more of STT-MRAM, MRAM, read-only memory (ROM) (e.g., EPROM, resistive read-only memory (RROM)), and Flash memory to be used in conjunction with the system memory 1316. The size of the non-volatile memory 1318 is typically selected to be just large enough to store any necessary operating system, application programs, and fixed data. Additionally, the non-volatile memory 1318 may include a high-capacity memory (e.g., disk drive memory, such as a hybrid-drive including resistive memory or other types of nonvolatile solid-state memory, for example). The non-volatile memory 1318 may include one or more apparatus 1000 and one or more electronic devices 100, 100″ according to embodiments of the disclosure.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. An electronic device comprising:
a source stack comprising one or more conductive materials;
a source contact adjacent to the source stack, at least a portion of the source contact comprising an epitaxial polysilicon material;
tiers of alternating conductive materials and dielectric materials adjacent to the source contact; and
pillars extending through the tiers and the source contact and into the source stack.

2. The electronic device of claim 1, wherein the source contact comprises the epitaxial polysilicon material between laterally adjacent portions of polysilicon.

3. The electronic device of claim 1, wherein the epitaxial polysilicon material exhibits a substantially circular cross-sectional shape.

4. The electronic device of claim 3, further comprising a portion of the epitaxial polysilicon material extending horizontally from the substantially circular cross-sectional shape.

5. The electronic device of claim 1, wherein a fill material is vertically adjacent to the epitaxial polysilicon material.

6. The electronic device of claim 5, wherein the fill material extends in a lateral direction between opposing sidewalls of the tiers of alternating conductive materials and dielectric materials and extends in a vertical direction to the epitaxial polysilicon material.

7. The electronic device of claim 1, wherein the source contact consists of the epitaxial polysilicon material.

8. The electronic device of claim 1, wherein the source contact is substantially free of polysilicon.

9. The electronic device of claim 1, further comprising a doped dielectric material between the source stack and the tiers of alternating conductive materials and dielectric materials, the epitaxial polysilicon material in direct contact with polysilicon of the source stack.

10. The electronic device of claim 9, wherein the epitaxial polysilicon material directly contacts a portion of sidewalls of the doped dielectric material.

11. An electronic system, comprising:
an input device;
an output device;
a processor device operably coupled to the input device and to the output device; and
one or more memory devices operably coupled to the processor device, the one or more memory devices comprising:
a source contact comprising at least a portion of epitaxial polysilicon adjacent to a source stack;
a doped dielectric material between the source stack and tiers of alternating conductive materials and dielectric materials adjacent to the doped dielectric material; and
memory pillars extending through the tiers of alternating conductive materials and dielectric materials and into the source stack, the source contact operably coupled to the memory pillars.

12. The electronic system of claim 11, wherein at least one of the source stack and the doped dielectric material comprises polysilicon.

13. The electronic system of claim 11, wherein at least one of the source stack, the doped dielectric material, and the source contact comprises doped polysilicon.

14. The electronic system of claim 11, wherein the epitaxial polysilicon comprises one or more dopants.

15. A method of forming an electronic device, comprising:
forming a source stack adjacent to a base material;
forming a source contact adjacent to the source stack;
forming a doped dielectric material adjacent to the source contact;
forming tiers of alternating nitride materials and dielectric materials adjacent to the doped dielectric material;
forming a slit through the tiers of alternating nitride materials and dielectric materials and into the source contact;
replacing the nitride materials in the tiers with conductive materials; and
forming a fill material in the slit, the fill material adjacent to the source contact.

16. The method of claim 15, wherein forming a source contact adjacent to the source stack comprises forming the source contact comprising a portion of epitaxial polysilicon between laterally adjacent portions of polysilicon of the source contact.

17. The method of claim 16, wherein forming a slit through the tiers of alternating nitride materials and dielectric materials comprises forming the portion of epitaxial polysilicon in the slit.

18. The method of claim 15, wherein forming a source contact adjacent to the source stack comprises forming the source contact consisting of epitaxial polysilicon adjacent to the source stack.

19. The method of claim 18, wherein forming the source contact consisting of epitaxial polysilicon comprises forming the epitaxial polysilicon between the source stack and the doped dielectric material and laterally adjacent to sidewalls of the doped dielectric material.

20. The method of claim 19, wherein forming the epitaxial polysilicon between the source stack and the doped dielectric material and laterally adjacent to sidewalls of the doped dielectric material comprises forming the epitaxial polysilicon on only a portion of sidewalls of the doped dielectric material.
